(19) United States
(12) Patent Application Publication
(10) Pub. No.: US 2022/0352272 A1
(43) Pub. Date: Nov. 3, 2022

(54) Back Plate and Method for Manufacturing the Same, Display Substrate and Method for Manufacturing the Same, and Display Device

(71) Applicant: BOE TECHNOLOGY GROUP CO., LTD., Beijing (CN)

(72) Inventor: Qing DAI, Beijing (CN)

(21) Appl. No.: 17/864,786

(22) Filed: Jul. 14, 2022

Related U.S. Application Data
(63) Continuation of application No. 16/433,240, filed on Jun. 6, 2019.

(30) Foreign Application Priority Data
Sep. 4, 2018 (CN) 201811025032.1

(51) Int. Cl. H01L 27/32; H01L 51/00; H01L 51/56

(52) U.S. Cl. CPC H01L 27/3246; H01L 51/0003; H01L 51/0005; H01L 51/56; H01L 51/5012

(57) ABSTRACT

The present disclosure provides a back plate for OLED display substrate, and a method for manufacturing the same. The back plate comprises a pixel definition layer comprising a body layer and an interface layer disposed on the surface of the body layer. The interface layer exhibits different lyophilic or lyophobic properties with respect to a functional layer of the OLED depending on the temperature of the interface layer. When the OLED display substrate is manufactured by using the back plate according the present disclosure, the cost can be reduced, and the device yield of the display substrate can be ensured.

### TECHNICAL FIELD

The present disclosure relates to the field of photoelectric displays, and in particular to a back plate for organic light emitting diode (OLED) display substrate and a method for manufacturing the same, a display substrate comprising the back plate and a method for manufacturing the same, and a display device comprising the display substrate.

### BACKGROUND TECHNOLOGY

In the current manufacturing process of OLED display substrate, it is an effective way to reduce the cost by using a solution process to form a pixel definition layer. However, if each layer is made by inkjet printing, it is costly because each layer needs to use more than one nozzle, which is a highly precise instrument and is easily plugged and thus scrapped after a certain period of use.

In order to reduce the manufacturing cost, slit coating, spin coating and the like are used in the prior art to perform overall coating, so as to prepare a common layer of the OLED display substrate. However, in the OLED display substrate prepared by such a process, the common layer cannot be formed with good properties, which will affect the yield of the organic electroluminescent diode display substrate.

Therefore, it is urgently desired in the art to design a back plate for OLED display substrate to reduce the manufacturing cost of the OLED display substrate and to ensure the device yield of the OLED display substrate.

### SUMMARY

An object of the present disclosure is to provide a back plate for OLED display substrate and a method for manufacturing the same, a display substrate comprising the back plate and a method for manufacturing the same, and a display device comprising the display substrate. When the OLED display substrate is manufactured by using the back plate, the cost can be reduced and the device yield of the display substrate can be ensured.

In order to solve at least one of the above problems, as a first aspect of the present disclosure, a back plate for OLED display substrate is provided. The back plate comprises a pixel definition layer, wherein the pixel definition layer comprises a body layer and an interface layer disposed on the body layer, and the interface layer exhibits different lyophilic or lyophobic properties with respect to a functional layer of the OLED depending on the temperature of the interface layer.

Optionally, the interface layer exhibits lyophobic to the functional layer of the OLED when the temperature of the interface layer exceeds a first predetermined temperature; whereas the interface layer exhibits lyophilic to the functional layer of the OLED when the temperature of the interface layer is equal to or lower than the first predetermined temperature.

Optionally, the interface layer comprises a temperature responsive material including any one of polystyrene-polyvinyl methyl ether, poly(caprolactone-styrene-acrylonitrile) copolymer, poly(methyl methacrylate-styrene-acrylonitrile) copolymer, poly(N-isopropyl acrylamide) and their combinations.

Optionally, the interface layer further comprises a plurality of nanoparticles, the nanoparticle comprises a nanocore having magnetic responsiveness and a shell covering the nanocore, wherein the nanoparticles accounts for no more than 5% by mass in the pixel definition layer, and the nanoparticles has a particle size of 10 nm to 30 nm.

The nanocore having magnetic responsiveness comprises ferroferric oxide (Fe₃O₄) particles and/or face-centered ferric oxide (γ-Fe₂O₃) particles, and the shell comprises silicon dioxide.

Optionally, the temperature responsive material is attached to the body layer by coupling reaction, so as to form the interface layer.

Optionally, the interface layer exhibits lyophobic to the functional layer of the OLED when the temperature of the interface layer is lower than a second predetermined temperature, and the interface layer exhibits lyophilic to the functional layer of the OLED when the temperature of the interface layer is higher than the second predetermined temperature, wherein the interface layer comprises a temperature responsive material which is any one of polystyrene-polyisoprene, poly(ethylene oxide)-poly(propylene oxide) and polyisobutylene-polydimethylsiloxane and the combinations thereof.

As a second aspect of the present disclosure, an OLED display substrate is provided. The display substrate comprises a back plate, and a plurality of functional layers including a plurality of common layers and a light emitting layer located between two common layers, wherein the back plate is the back plate provided in the present disclosure.

As a third aspect, the present disclosure provides a display device comprising the above-described OLED display substrate provided in the present disclosure.

As a fourth aspect of the present disclosure, a method for manufacturing a back plate is provided, wherein the back plate is the above-described back plate provided in the present disclosure, and the manufacturing method comprises a step of forming a pixel definition layer including:

mixing a plurality of the nanoparticles with a solution of the temperature responsive material to obtain an initial mixture, wherein the nanoparticle comprises a nanocore having magnetic responsiveness and a shell covering the nanocore, the nanoparticles accounts for no more than 5% by mass in the pixel definition layer, and the nanoparticles has a particle size of 10 nm to 30 nm; the temperature responsive materials include any one of polystyrene-polyvinyl methyl ether, poly(caprolactone-styrene-acrylonitrile) copolymer, poly(methyl methacrylate-styrene-acrylonitrile) copolymer, poly(N-isopropyl acrylamide) and the combinations thereof;

mixing the initial mixture with a stock solution of the body layer to obtain an intermediate mixture;

coating the intermediate mixture on a base substrate to form an initial layer;

patterning the initial layer to obtain an initial pixel definition layer having a shape consistent with that of the pixel definition layer; and

disposing the base substrate with the initial pixel definition layer thereon in a magnetic field and curing the initial pixel definition layer, such that the stock solution of the body layer is cured to obtain the body layer, and that meanwhile the nanoparticles grafted with the temperature responsive material on their surface move to the surface of the body layer and are cured to form the interface layer, wherein the nanocore having magnetic responsiveness comprises ferroferric oxide particles and/or face-centered ferric oxide particles, and the shell covering the nanocore comprises silicon dioxide.

Alternatively, the step of forming the pixel definition layer comprises:

forming the body layer;

plasma-processing the body layer by using a plasma;

providing a coupling agent on the surface of the body layer after plasma-processing;

coating a solution of the temperature responsive material including any one of polystyrene-polyvinyl methyl ether, poly(caprolactone-styrene-acrylonitrile) copolymer, poly(methyl methacrylate-styrene-acrylonitrile) copolymer, poly(N-isopropyl acrylamide) and the combinations thereof; and

reacting the temperature responsive material with the coupling agent to form the interface layer.

As a fifth aspect, the present disclosure provides a method for manufacturing an OLED display substrate comprising:

manufacturing a back plate provided in the present disclosure;

forming a plurality of functional layers, which comprises forming each common layers and forming a light emitting layer;

wherein forming each common layers comprises:
adjusting the process temperature such that the surface of the interface layer exhibits lyophilic;
coating material for a common layer on the surface of the interface layer; and
adjusting the process temperature such that the surface of the interface layer exhibits lyophobic, which allows the material for the common layer to be concentrated into pixel openings of the pixel definition layer, and further be cured to form a common layer;

forming the light emitting layer include:
adjusting the process temperature such that the surface of the interface layer exhibits lyophobic;
printing material for the light emitting layer in the pixel openings of the pixel definition layer to form the light emitting layer.

### BRIEF DESCRIPTION OF THE DRAWINGS

The drawings are intended to provide a further understanding of the present disclosure, and are intended to be a part of the description to explain the present disclosure together with the embodiments below. This is not, however, a limitation of the present disclosure. In the drawings:

FIG. 1 is a schematic diagram of the back plate for OLED display substrate provided in the present disclosure;

FIG. 2 is a schematic diagram of the OLED display substrate comprising the back plate provided in the present disclosure;

FIG. 3 is a schematic flow chart of a first embodiment of the method for manufacturing a back plate for the OLED display substrate provided in the present disclosure;

FIG. 4 is a schematic flow chart of a second embodiment of the method for manufacturing a back plate for the OLED display substrate provided in the present disclosure; and

FIG. 5 is a schematic flow chart of an embodiment of the method for manufacturing an OLED display substrate provided in the present disclosure.

### DETAILED DESCRIPTION OF THE EMBODIMENTS

The specific embodiments of the present disclosure will be described in detail below with reference to the accompanying drawings. It should be understood that the specific embodiments described herein are merely illustrative and are not restrictive to the present disclosure.

In the prior art, a material with low surface energy and hydrophobicity was used as the pixel definition layer on the surface of the back plate of the OLED display substrate, and a common layer material is applied on the pixel definition layer by using a faster, more efficient coating process when fabricating a common layer of the OLED display substrate; however, due to the faster coating speed, material for the common layers could not well wet the pixel definition layer during coating, thereby resulting an incomplete coating layer and a risk of the material being thrown off. The above risks are more serious especially for the spin coating process.

As a result of an intensive study, it has been found by the inventor that, by making the surface of the pixel definition layer lyophilic, it is possible to avoid the material for the common layers being thrown off during coating and to make the coating layer more complete. After the coating is completed, the surface of the pixel definition layer is changed to be lyophobic by adjusting its temperature so that the material for the common layers can flow and concentrate to the nearest pixel opening to form the common layers of OLED.

Since materials for the light emitting layer in different pixel sub-units are different from each other, in order to avoid mixing of the materials of different pixel sub-units, the corresponding materials are printed into pixel openings by means of inkjet printing which could achieve precise location. At this time, the surface of the pixel definition layer is adjusted to be lyophobic, so that ink for the light emitting layer can be prevented from remaining on a portion of the pixel definition layer other than the pixel openings.

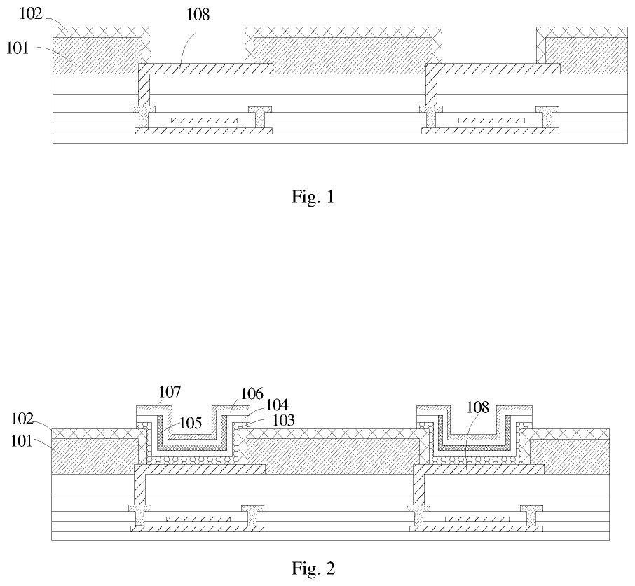

Based on the above inventive concepts, as the first aspect of the present disclosure, a back plate for OLED display substrate is provided. As shown in FIG. 1, the back plate comprises a pixel definition layer comprising a body layer 101 and an interface layer 102 disposed on the surface of the body layer. The interface layer 102 exhibits different lyophilic or lyophobic properties with respect to a functional layer of the OLED depending on the temperature of the interface layer 102.

It is easy to understand that the back plate comprises a plurality of pixel sub-units, each of which corresponds to one OLED. As shown in FIG. 1, the pixel definition layer comprises a plurality of pixel openings arranged with an interval therebetween, and a portion of the OLED is disposed within the pixel openings. In addition to the pixel definition layer, the back plate further comprises a base substrate, a pixel circuit formed of a plurality of thin film transistors (TFTs) and a plurality of anodes 108 of corresponding OLEDs.

The back plate provided in the present disclosure is suitable for OLED display substrate in which each functional layer of the OLED is formed by a solution method.

Therefore, in the present disclosure, the interface layer 102 exhibits different lyophilic or lyophobic properties with respect to a functional layer of the OLED depending on the temperature thereof. When performing the film formation process for the functional layers of the OLED, the temperature of the interface layer 102 is adjusted according to the requirements of the film formation process, thereby controlling the lyophilic or lyophobic properties of the interface layer 102.

The functional layer of the OLED comprises a light emitting layer and a plurality of common layers. Specifically, when each common layer is formed, the process temperature is firstly adjusted such that the interface layer 102 exhibits lyophilic at this temperature, and then the coating process is employed to apply material for the common layers over the entire interface layer. Since the interface layer 102 is lyophilic, the material for the common layers can be sufficiently spread on the interface layer 102 to form a good coating film without aggregation during coating. Even the material for the common layer located within the pixel opening can be well bonded to the sidewalls of the pixel opening to form a uniform coating film. Further, even when the spin coating method is used, the material for the common layers would not be thrown off by the spin coating roller.

After the coating is completed, the process temperature is adjusted again such that the interface layer 102 exhibits lyophobic at this temperature, which allows the material for the common layers on the portion of the pixel definition layer other than the pixel openings flow toward the pixel openings, further ensuring the material for the common layers within the pixel openings to form a continuous film.

As a preferred embodiment, the solvents in the material for the common layers can be removed by reduced pressure method to form a dried thin layer.

Compared with forming the common layers by inkjet printing, the common layers is formed with improved efficiency, reduced production cost, and higher yield by coating method when using the back plate of the present disclosure.

In addition, when the light emitting layer is formed by inkjet printing, the process temperature is adjusted such that the interface layer is lyophobic, and the ink for the light emitting layer can be prevented from remaining on the portion of the pixel definition layer other than the pixel openings, which will result in unnecessary color mixing, thereby effectively improving the device yield of the obtained OLED display substrate.

In the present disclosure, how to adjust the temperature is not particularly limited. For example, the back plate may be heated by any one of infrared heating, electromagnetic heating, and microwave heating to change the temperature thereof, thereby making the interface layer exhibit lyophilic or lyophobic. Correspondingly, the back plate can be cooled by cold plate cooling, magnetic cooling, etc., to change the temperature thereof, thereby making the interface layer exhibit lyophilic or lyophobic.

In the present disclosure, the body layer may contain a polyimide material; and the interface layer comprises a temperature responsive material (i.e. exhibiting lyophilic or lyophobic depending on the temperature). The temperature responsive material can be a material with lower critical solution temperature (LCST) or a material with upper critical solution temperature (UCST).

If the interface layer contains a material with lower critical solution temperature, the interface layer exhibits lyophobic to the functional layer of the OLED when the temperature of the interface layer exceeds the lower critical solution temperature (the first predetermined temperature), and exhibits lyophilic to the functional layer of the OLED when the temperature of the interface layer is equal to or lower than the lower critical solution temperature (the first predetermined temperature).

If the interface layer contains a material with upper critical solution temperature, the interface layer exhibits lyophobic to the functional layer of the OLED when the temperature of the interface layer is lower than the upper critical solution temperature (the second predetermined temperature), and exhibits lyophilic to the functional layer of the OLED when the temperature of the interface layer is not lower than the upper critical solution temperature (the second predetermined temperature).

The temperature responsive materials with lower critical solution temperature include any one of polystyrene-polyvinyl methyl ether, poly(caprolactone-styrene-acrylonitrile) copolymer, poly(methyl methacrylate-styrene-acrylonitrile) copolymer, and poly(N-isopropyl acrylamide) and the combinations thereof.

In this case, a temperature responsive material can be attached to the body layer by coupling reaction so as to form the interface layer.

For example, the active centers are formed on the surface of the body layer by plasma processing, and then a coupling agent such as vinyltriethoxysilane is introduced. The functional groups of triethoxysilane react with the active centers, allowing the vinyl groups distributed on the periphery of the molecules. The vinyl groups are then grafted onto the temperature responsive material by radical polymerization method to form the interfacial layer.

The disclosure is not limited to the above, and the interface layer may further comprise a plurality of nanoparticles when the interface layer comprises the temperature responsive material with lower critical solution temperature. The nanoparticle comprises a nanocore having magnetic responsiveness and a shell covering the nanocore. The nanoparticles accounts for no more than 5% by mass in the pixel definition layer. The nanocore having magnetic responsiveness comprises, but is not limited to, ferroferric oxide particles and/or face-centered ferric oxide particles; the material of the shell comprises silicon dioxide.

The method for manufacturing the above-described pixel definition layer will be discussed below to illustrate why the nanoparticles are disposed in the interface layer.

In the above case, the method for manufacturing the pixel definition layer comprises:

mixing a plurality of the nanoparticles with a solution of the temperature responsive material to obtain an initial mixture, wherein the nanoparticle is grafted with the molecules of the temperature responsive material on its surface;

mixing the initial mixture with a stock solution of the body layer to obtain an intermediate mixture;

spin coating the intermediate mixture on a base substrate to form an initial layer;

patterning the initial layer to obtain an initial pixel definition layer; and

disposing the base substrate with the initial pixel definition layer thereon in a magnetic field and curing the initial pixel definition layer.

Nanoparticles can be prepared using conventional techniques, such as a sol-gel method to coat silicon dioxide on the surface of the nanocore. Further, a temperature responsive material can be grafted onto the surface of the nanoparticles by conventional techniques, such as an atom transfer radical polymerization method or the like.

In this method, by virtue of the magnetic responsiveness of the ferroferric oxide particles or the face-centered ferroferric oxide particles, the nanoparticles grafted with the temperature responsive material thereon are moved to the surface of the body layer under the magnetic field, so as to form an interface layer during curing.

Further, since the face-centered ferric oxide has a magnetothermal effect, the adjustment of temperature can be achieved by disposing the back plate in a magnetic field, and thereby improving the heating efficiency.

As an embodiment, the nanoparticles have a particle size ranging from 10 nm to 30 nm, and preferably 20 nm. The nanoparticles in the above particle size range will exhibit superparamagnetic properties. Therefore, after the magnetic field is removed, the nanoparticles do not have a magnetic remanence. That is, the light emission of the subsequently obtained OLED devices will not be affected by the interface layer due to magnetic remanence.

Due to the small size of the nanoparticles, the nanoparticles have a high specific surface area and a high surface activity, thereby facilitating the grafting of the temperature responsive materials onto the surface of the nanoparticles. Further, since the silicon dioxide itself has a high surface activity, covering the nanocore with silicon dioxide is more advantageous for grafting the temperature responsive material onto the surface of the nanoparticle.

The nanoparticles accounts for no more than 5% by mass in the pixel definition layer, such that the nanoparticles affect neither the chemical stability nor the mechanical properties (the mechanical properties herein are mechanical properties between microscopic particles rather than macroscopic mechanical properties) of the interface layer.

The method of patterning the initial coating layer can be selected with different steps depending on whether the coating layer has a photosensitivity. If the coating layer has a photosensitivity, exposure can be directly performed under obscuration of a mask, and then the patterned coating layer is obtained by developing and etching. If the coating layer has no photosensitivity, a photoresist layer is applied on the coating layer firstly, and then the exposure is performed under obscuration of a mask before developing and etching, and finally removing the photoresist on the surface to obtain the patterned coating layer.

Generally, it is necessary to dry the finished or semi-finished OLED display substrate in manufacturing the OLED display substrate. The temperature window of the drying process is room temperature (from 25° C. to 35° C.). Preferably, the temperature responsive material of the present disclosure is poly(N-isopropyl acrylamide) with a lower critical solution temperature of 32° C., so that the lyophilic or lyophobic properties of the interface layer can be adjusted by using a drying chamber, facilitating to reduce the cost of the process.

Preferably, the temperature responsive material with upper critical solution temperature includes any one of polystyrene-polyisoprene, poly(ethylene oxide)-poly(propylene oxide), polyisobutylene-polydimethylsiloxane and the combinations thereof.

As the second aspect of the present disclosure, an OLED display substrate is provided. The display substrate comprises a back plate provided in the present disclosure, and a plurality of functional layers comprising a light emitting layer and a plurality of common layers.

The OLED display substrate is manufactured by using the back plate as shown in FIG. 1, and a plurality of common layers are formed on the surface of the pixel definition layer by spin coating method, wherein the plurality of common layers comprises the hole injection layer 103, the hole transport layer 104, the electron injection layer 107 and the electron transport layer 106 as shown in FIG. 2. Among the formations of the plurality of common layers, the light emitting layer 105 is forming by inkjet printing, and the light emitting layer 105 is located between the hole transport layer 104 and the electron transport layer 106. However, the present disclosure is not limited to this. For example, the light emitting layer made of certain specific materials has a capability of transmitting electrons, thus the electron transport layer 106 may be omitted. In other word, the light emitting layer 105 is located in the hole transport layer 104 and the electron injection layer 107, thereby saving the cost of the process.

Preferably, in the above process of forming the plurality of common layers, the interface layer is allowed to exhibit lyophilic by adjusting the process temperature so that materials for the common layers can be sufficiently spread on the interface layer 102 to form a good coating layer. The temperature is then adjusted such that the interface layer 102 exhibits lyophobic, allowing materials for the common layers to be concentrated from the surface of the interface layer 102 into the pixel openings at a relatively lower location to form the common layer.

As the third aspect of the present disclosure, a display device comprising the above-described OLED display substrate is provided.

As the fourth aspect of the present disclosure, a method for manufacturing the above-described back plate for OLED display substrate is provided. The method comprises:

forming a pixel definition layer comprising a body layer and an interface layer disposed on the surface of the body layer, wherein the interface layer exhibits lyophilic or lyophobic to the functional layer of the OLED depending on the temperature of the interface layer.

It is easy to understand that the back plate comprises a plurality of pixel sub-units, each of which corresponds to one OLED. As shown in FIG. 1, the pixel definition layer comprises a plurality of pixel openings arranged with an interval therebetween, and a portion of the OLED is disposed within the pixel openings. In addition to the pixel definition layer, the back plate further comprises a base substrate, a pixel circuit formed of a plurality of thin film transistors (TFTs) and a plurality of anodes 108 of corresponding OLEDs.

In manufacturing the OLED display substrate, the common layers are formed by a solution method.

In the present disclosure, the interface layer 102 exhibits lyophilic or lyophobic to the functional layer of the OLED depending on its temperature. When forming the functional layer of the OLED, the temperature of the interface layer 102 is adjusted as required to make the interface layer 102 be lyophilic or lyophobic.

The functional layer of the OLED comprises a light emitting layer and a plurality of common layers. Specifically, coating process is used to form the common layers, and a portion of the obtained coatings is in the pixel openings. Since the interface layer 102 exhibits lyophilic at this process, materials for the common layers can be sufficiently spread on the interface layer 102 to form a coating having good continuity, without being thrown off or agglomerated during the coating process.

After the coating is completed, the process temperature is adjusted such that the interface layer 102 is converted from lyophilic to lyophobic, and the materials for the common layers are concentrated from the surface of the interface layer 102 into the pixel openings at a relatively lower location to form the common layers of the OLED.

By using the back plate of the present disclosure, the common layers can be formed by coating process with improved efficiency, reduced production cost and higher product yield, compared to the formation of the common layer by means of inkjet printing.

Moreover, when the light emitting layer is formed by inkjet printing, the surface of the pixel definition layer exhibits lyophobic, so as to avoid undesired color mixing between the adjacent OLEDs and thereby improving the device yield of the obtained OLED display substrate.

In the present disclosure, the body layer may comprise polyimide materials; and the interface layer comprises a temperature responsive material (i.e. exhibiting lyophilic or lyophobic depending on the temperature). The temperature responsive material can be a material with lower critical solution temperature or a material with upper critical solution temperature.

If the interface layer contains a material with lower critical solution temperature, the interface layer exhibits lyophobic to the functional layer of the OLED when the temperature of the interface layer exceeds the lower critical solution temperature (the first predetermined temperature), and exhibits lyophilic to the functional layer of the OLED when the temperature of the interface layer is equal to or lower than the lower critical solution temperature (the first predetermined temperature).

If the interface layer contains a material with upper critical solution temperature, the interface layer exhibits lyophobic to the functional layer of the OLED when the temperature of the interface layer is lower than the upper critical solution temperature (the second predetermined temperature), and exhibits lyophilic to the functional layer of the OLED when the temperature of the interface layer is not lower than the upper critical solution temperature (the second predetermined temperature).

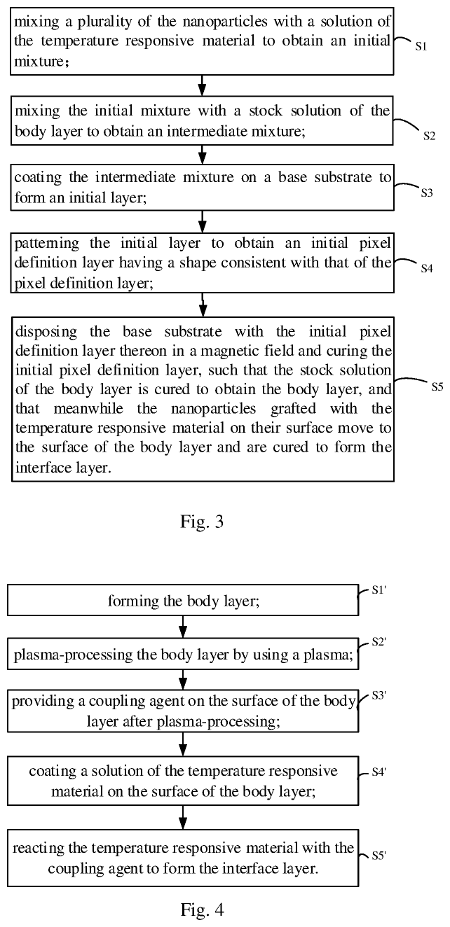

As an embodiment of the present disclosure, when the interface layer comprises a material with lower critical solution temperature, forming the pixel defining layer comprises the following steps as shown in FIG. 3:

Step S1: mixing a plurality of the nanoparticles with a solution of the temperature responsive material to obtain an initial mixture, wherein the nanoparticle comprises a nanocore having magnetic responsiveness and a shell covering the nanocore, the nanoparticles accounts for no more than 5% by mass in the pixel definition layer, and the nanoparticles has a particle size of 10 nm to 30 nm; the temperature responsive materials include any one of polystyrene-polyvinyl methyl ether, poly(caprolactone-styrene-acrylonitrile) copolymer, poly(methyl methacrylate-styrene-acrylonitrile) copolymer, poly(N-isopropyl acrylamide) and the combinations thereof;

Step S2: mixing the initial mixture with a stock solution of the body layer to obtain an intermediate mixture;

Step S3: spin coating the intermediate mixture on a base substrate to form an initial coating;

Step S4: patterning the initial layer to obtain an initial pixel definition layer having a shape consistent with that of the pixel definition layer; and

Step S5: disposing the base substrate with the initial pixel definition layer thereon in a magnetic field and curing the initial pixel definition layer, such that the stock solution of the body layer is cured to obtain the body layer and that meanwhile the nanoparticles grafted with the temperature responsive material on their surface move to the surface of the body layer and are cured to form the interface layer, wherein the nanocore having magnetic responsiveness comprises ferroferric oxide particles and/or face-centered ferric oxide particles, and the shell covering the nanocore comprises silicon dioxide.

As described above, in step S1, a plurality of nanoparticles is mixed with the solution of the temperature responsive material to obtain an initial mixture, wherein the temperature responsive material is grafted onto the surface of the plurality of the nanoparticles.

In step S2, solute in the stock solution of the body layer is materials for forming the body layer, such as polyimides.

Step S3 and step S4 are performed to obtain the initial pixel definition layer. It is noted that, in the process of patterning the initial coating layer, the method further comprises forming a plurality of pixel openings arranged with an interval therebetween in the initial pixel definition layer.

In step S5, the initial pixel definition layer is cured, such that the stock solution of the body layer is cured to form the body layer, and that the nanoparticles with the temperature responsive material grafted thereon, in the later stage of curing, move to the surface of the body layer by magnetic field induction and then are cured to form the interface layer.

It should be noted that, the ferroferric oxide particles and/or the surface-structured ferric oxide particles are selected as the nanocore with magnetic responsiveness in the present disclosure for the following considerations.

First, by virtue of the magnetic responsiveness of the ferroferric oxide particles and/or the face-centered ferroferric oxide particles, the nanoparticles with the temperature responsive material grafted thereon can move to the surface of the body layer, so as to form the interface layer.

Second, since the nanoparticles have a magnetothermal effect in the magnetic field environment, the temperature responsive material grafted around the nanoparticles can be heated in high efficiency and high rate. Moreover, the temperature adjustment can be achieved by placing the back plate within a magnetic field.

In the above embodiment, the nanoparticles have a particle size ranging from 10 nm to 30 nm, and preferably the nanoparticles have a particle size of 20 nm. The nanoparticles in the above particle size range will exhibit superparamagnetic properties. Therefore, after the magnetic field is removed, the nanoparticles do not have a magnetic remanence. In other words, the light emission of the subsequently obtained OLED devices will not be affected by the interface layer due to magnetic remanence.

It is easily understood that due to the small size of the nanoparticles, the nanoparticles have a high specific surface area and a high surface activity, thereby facilitating the grafting of temperature responsive materials onto the surface of the nanoparticles. Further, since the silicon dioxide itself has a high surface activity, it is more advantageous for grafting a temperature responsive material onto the surface of the nanoparticle. The nanoparticles in the pixel definition layer does not exceed 5% by mass, such that the nanoparticles affect neither the chemical stability nor the mechanical properties (the mechanical properties herein are mechanical properties between microscopic particles rather than macroscopic mechanical properties) of the interface layer.

In the present disclosure, when the interface layer contains a temperature responsive material with lower critical solution temperature, as another embodiment, as shown in FIG. 4, the step of forming the pixel defining layer comprises:

Step S1′: forming the body layer;

Step S2′: plasma-processing the body layer by using plasma;

Step S3′: providing a coupling agent on the surface of the body layer after plasma-processing;

Step S4′: coating a solution of the temperature responsive material including any one of polystyrene-polyvinyl methyl ether, poly(caprolactone-styrene-acrylonitrile) copolymer, poly(methyl methacrylate-styrene-acrylonitrile) copolymer, poly(N-isopropyl acrylamide) and the combinations thereof; and

Step S5′: reacting the temperature responsive material with the coupling agent to form the interface layer.

As described above, in step S1′, the body layer is formed on the base substrate. As a preferred embodiment, material forming the body layer may be a polyimides material. Further, forming the body layer further comprises forming a plurality of pixel openings arranged with an interval therebetween.

In step S2′, the body layer is processed with plasma to form active centers on the surface of the body layer. Preferably, the plasma can be argon (Ar) plasma.

In step S3′, specifically, a silane coupling agent with vinyl group can be employed to form vinyl groups on the surface of the body layer after the plasma processing. The silane coupling agent with vinyl group is introduced such that the silane coupling agent reacts with the active centers formed on the surface of the body layer, thereby forming a layer of vinyl group on the surface of the body layer. Preferably, the silane coupling agent with vinyl group can be vinyltriethoxysilane.

In step S4′ and step S5′, the temperature responsive material is grafted to the vinyl groups via a radical polymerization method to form the interface layer. Preferably, the temperature responsive material can be poly(N-isopropyl acrylamide).

In the present disclosure, when the interface layer contains a material having an upper critical solution temperature, such material preferably includes any one of polystyrene-polyisoprene, poly(ethylene oxide)-poly(propylene oxide), polyiso-butylene-polydimethylsiloxane and the combinations thereof.

As the fifth aspect, the present disclosure provides a method for manufacturing an OLED display substrate comprising:

manufacturing a back plate according to the method provided in the present disclosure;

forming a plurality of functional layers, which includes forming each common layers and forming a light emitting layer between forming two common layers,

wherein forming each common layers comprises:
adjusting the process temperature such that the surface of the interface layer exhibits lyophilic;
coating material for a common layer on the surface of the interface layer; and
adjusting the process temperature such that the surface of the interface layer exhibits lyophobic, which allows the material for the common layer to be concentrated into pixel openings of the pixel definition layer and further be cured to form a common layer;

forming the light emitting layer include:
adjusting the process temperature such that the surface of the interface layer exhibits lyophobic;
printing material for the light emitting layer in the pixel openings of the pixel definition layer, such that the material for the light emitting layer concentrate into the pixel openings so as to form the light emitting layer.

As described above, by using the back plate, a plurality of common layers is formed on the back plate by a coating method. It is noted that the common layers comprises a hole injection layer, a hole transport layer, an electron transport layer and an electron injection layer. During the manufacturing, the plurality of common layers are not sequentially performed, and forming a light emitting layer is further included between forming the hole transport layer and forming the electron transport layer, and then the electron transport layer and the electron injection layer are formed sequentially. If the material for the light emitting layer itself has certain electron transport characteristics, the electron transport layer can be directly formed after forming the light emitting layer, thereby reducing one membrane process and saving the cost.

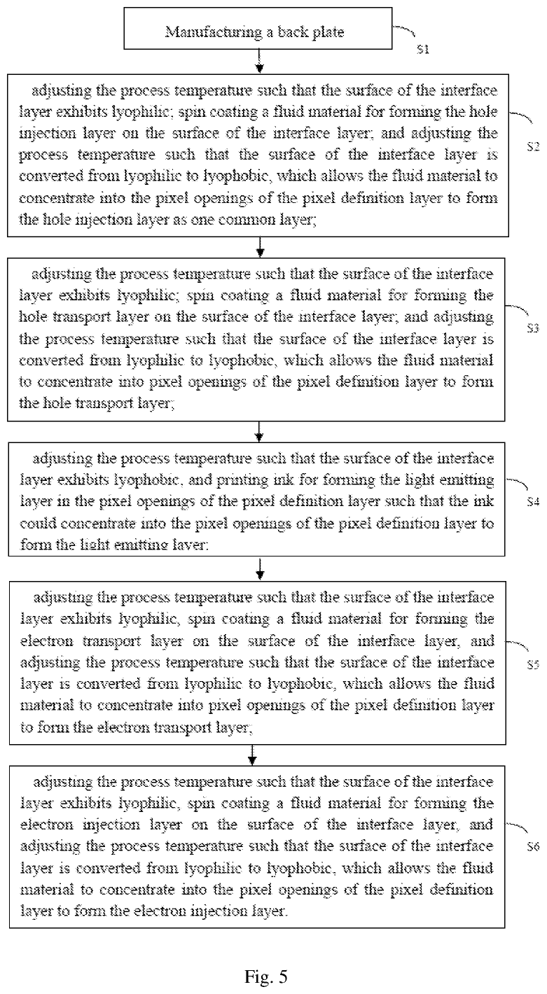

In order to facilitate the understanding of the above-described manufacturing method of the OLED display substrate, as shown in FIG. 5, a preferred embodiment of the method comprises:

Step 1: manufacturing a backboard according to the manufacturing method provided in the present disclosure;

Step 2: adjusting the process temperature such that the surface of the interface layer exhibits lyophilic; spin coating a fluid material for forming the hole injection layer on the surface of the interface layer; and adjusting the process temperature such that the surface of the interface layer is converted from lyophilic to lyophobic, which allows the fluid material for forming the hole injection layer to concentrate into the pixel openings of the pixel definition layer to form the hole injection layer as one common layer.

In the above step of forming the hole injection layer, the process temperature is adjusted such that the interface layer exhibits lyophilic, and the coating method is used to enable the fluid material for forming the hole injection layer to be sufficiently spread on the interface layer to form a good coating, and then the process temperature is adjusted such that the interface layer exhibits lyophobic, which allows the fluid material for forming the hole injection layer to enter the pixel openings at a relatively lower location from the surface of the interface layer. The solvent of the fluid material of the hole injection layer is then removed and dried to form the hole injection layer.

Step 3: adjusting the process temperature such that the surface of the interface layer exhibits lyophilic; spin coating a fluid material for forming the hole transport layer on the surface of the interface layer; and adjusting the process temperature such that the surface of the interface layer is converted from lyophilic to lyophobic, which allows the fluid material for forming the hole transport layer to concentrate into pixel openings of the pixel definition layer to form the hole transport layer as one common layer.

In the above step of forming the hole transport layer, the process temperature is adjusted such that the interface layer exhibits lyophilic, and the coating method is used to enable the fluid material for forming the hole transport layer to be sufficiently spread on the interface layer to form a good coating, and then the process temperature is adjusted such that the interface layer exhibits lyophobic, which allows the fluid material for forming the hole transport layer to enter the pixel openings at a relatively lower location from the surface of the interface layer. The solvent of the fluid material of the hole transport layer is then removed and dried, thereby forming the hole transport layer.

Step 4: adjusting the process temperature such that the surface of the interface layer exhibits lyophobic, and printing a ink for forming the light emitting layer in the pixel openings of the pixel definition layer such that the ink for forming the light emitting layer could concentrate into the pixel openings of the pixel definition layer to form the light emitting layer.

In the step of forming the light emitting layer, the process temperature is adjusted such that the interface layer exhibits lyophobic, and the ink corresponding to the light emitting color of the pixel sub-unit is printed into the corresponding pixel opening by inkjet printing. The solvent of the ink is removed and dried, thereby forming the light emitting layer. Since the interface layer exhibits lyophobic, the ink sputtered outside the pixel opening during inkjet printing may converge from the surface of the interface layer to the pixel openings at a relatively lower location, thus the ink for forming the light emitting layer is not remained on the surface of the interface layer.

Step 5: adjusting the process temperature such that the surface of the interface layer exhibits lyophilic, spin coating a fluid material for forming the electron transport layer on the surface of the interface layer, and adjusting the process temperature such that the surface of the interface layer is converted from lyophilic to lyophobic, which allows the fluid material for forming the electron transport layer to concentrate into pixel openings of the pixel definition layer to form the electron transport layer as one common layer.

In the above step of forming the electron transport layer, the process temperature is adjusted such that the interface layer exhibits lyophilic, and the coating method is used to enable the fluid material for forming the electron transport layer to be sufficiently spread on the interface layer to form a good coating, and then the process temperature is adjusted such that the interface layer exhibits lyophobic, which allows the fluid material for forming the electron transport layer to enter the pixel openings at a relatively lower location from the surface of the interface layer. The solvent of the fluid material of the electron transport layer is then removed and dried, thereby forming the electron transport layer.

Step 6: adjusting the process temperature such that the surface of the interface layer exhibits lyophilic, spin coating a fluid material for forming the electron injection layer on the surface of the interface layer, and adjusting the process temperature such that the surface of the interface layer is converted from lyophilic to lyophobic, which allows the fluid material for forming the electron injection layer to concentrate into the pixel openings of the pixel definition layer to form the electron injection layer as one common layer.

In the above step of forming the electron injection layer, the process temperature is adjusted such that the interfacial layer exhibits lyophilic, and the fluid material for forming the electron injection layer can be sufficiently spread on the interface layer to form a good coating by spin coating, and then the process temperature is adjusted such that the interface layer exhibits lyophobicity, which allows the fluid material for forming the electron injection layer to enter the pixel openings at a relatively lower location from the surface of the interface layer. The solvent of the fluid material for forming the electron injection layer is then removed and dried, thereby forming the electron injection layer.

In the above embodiment, compared to forming the common layers by means of inkjet printing, forming the common layers by spin coating improves the efficiency, thereby reducing the production cost. In addition, the surface of the pixel definition layer is lyophobic when forming the light emitting layer by inkjet printing, which avoids unnecessary color mixing between the adjacent OLED elements, thereby improving the device yield of the obtained OLED display substrate.

The method for forming the common layers is not limited in the present disclosure. For example, the coating method may be any one of spin coating, slit coating, and spray coating, but is not limited thereto.

It should be noted that the manner of adjusting the process temperature includes heating and cooling, and it may be selected depending on the specific requirements (i.e., the interface layer should be lyophilic or lyophobic). In addition, the specific manner of heating and cooling is not limited in the present disclosure. As an embodiment, the heating method may be hot plate heating, infrared heating, electromagnetic heating, or microwave heating, and the cooling method may be cold plate cooling or a magnetic cooling.

When the common layers and the light emitting layer are formed by using the back plate provided in the present disclosure, the dynamic adjustment of the lyophilic or lyophobic properties of the interface layer in the pixel definition layer can be achieved by adjusting the temperature, which is simple and practicable, and the obtained common layers and light emitting layer are free from contamination and damage.

### EXAMPLES

### Example 1

Manufacture of a Back Plate Comprising a Temperature Responsive Material with Lower Critical Solution Temperature

Magnetic Fe₃O₄ nanoparticles (average particle size of 15 nm, 1 g) were mixed with 20 ml of water and 60 ml of ethanol, and then 1.5 ml of concentrated ammonia (28%) was added. Then, the reaction flask containing the above mixture was ultrasonically shaken in a water bath for mixing. Then, a mixture of 0.45 ml of TEOS and 10 ml of ethanol was slowly added dropwise to the above solution, and after stirring for 12 hours, the reactant was magnetically separated and repeatedly washed with ethanol for 3 times to obtain magnetic Fe₃O₄ nanoparticles coated with silicon dioxide.

The magnetic Fe₃O₄ nanoparticles coated with silicon dioxide were dispersed in deionized water to obtain a dispersion of the nanoparticles (20 mg/ml). The dispersion of the nanoparticles was added to an aqueous solution containing N-isopropyl acrylamide, N,N-methylenebisacrylamide and potassium persulfate. The mixture was mechanically stirred and dispersed, and then deoxygenated by flushing with nitrogen. Then the mixture is heated to 85° C. for reacting under nitrogen atmosphere. After the reaction was complete, the product was collected by centrifugation and washed with water.

The nanoparticles prepared above were incorporated into a stock solution (polyimide solution) of the pixel definition layer, and the content of the nanoparticles in the stock solution should not be higher than 5% by mass. The uniformly mixed solution was spin coated on the base substrate, prebaked at 90° C. for 100 s, and patterned by exposure and developing. Then, a magnetic field exerting an upward magnetic force was applied directly above the surface of the base substrate and curing was continued for 1 hour to form a pixel definition layer on the base substrate.

### Example 2

Manufacture of a Back Plate Comprising a Temperature Responsive Material with Upper Critical Solution Temperature

On the base substrate, a polyimide body layer was prepared by spin coating and baking method. Active centers were formed on the surface of the body layer by Ar plasma. The base substrate processed by Ar plasma was placed in an ammonia solution of vinyltriethoxysilane, and mixed by ultrasonication at 40° C. for 100 s. The obtained base substrate was washed with water and then polystyrene-polyisoprene was grafted onto the base substrate as follows.

The polyisoprene initiator was dissolved in toluene, and methyl methacrylate and styrene were added thereto respectively. Then the mixed solution is sprayed onto the base substrate under ultraviolet light irradiation and reacted under ultrasonication for 120 s. The base substrate was then washed with a solvent such as PGMEA. Thus, the base substrate of which the surface modified with copolymer was obtained.

### Example 3 Manufacture of the OLED Display Substrate

The OLED display substrate was manufactured based on the back plate in Example 1.

The interface layer temperature of the back plate in Example 1 was adjusted to 25° C. (lower than the lower critical solution temperature of poly(N-isopropyl acrylamide), about 32° C.) by cold plate cooling. The fluid material for forming the hole injection layer was spin coated, and then the solvent was removed under reduced pressure to form a shaped thin coating. After that, the spin-coated substrate was moved to a hot plate and baked to remove the remained solvent from the thin coating, thereby forming the final hole injection layer.

The interface layer temperature of the obtained back plate was adjusted to 25° C. by cold plate cooling. The fluid material for forming the hole transport layer was spin coated, and then the solvent was removed under reduced pressure to form a shaped thin coating. After that, the spin-coated substrate was moved to a hot plate and baked to remove the remained solvent from the thin coating, thereby forming the final hole transport layer.

The interface layer temperature of the obtained back plate was adjusted to 40° C. (higher than the upper critical solution temperature of poly(N-isopropyl acrylamide), about 32° C.) by hot plate heating. The ink for forming the light emitting layer was printed in the pixel openings of the pixel definition layer and dried under reduced pressure, thereby forming the light emitting layer.

The interface layer temperature of the obtained back plate was adjusted to 25° C. by cold plate cooling. The fluid material for forming the electron transport layer was spin coated, and then the solvent was removed under reduced pressure to form a shaped thin coating. After that, the spin-coated substrate was moved to a hot plate and baked to remove the remained solvent from the thin coating, thereby forming the final electron transport layer.

The interface layer temperature of the obtained back plate was adjusted to 25° C. by cold plate cooling. The fluid material for forming the electron injection layer was spin coated, and then the solvent was removed under reduced pressure to form a shaped thin coating. After that, the spin-coated substrate was moved to a hot plate and baked to remove the remained solvent from the thin coating, thereby forming the final electron injection layer.

The electron transport layer and the electron injection layer film may also be formed by evaporation. In this case, the temperature control and adjustment are not required in the preparation process, which is the same as the conventional method for manufacturing the substrate, and detailed description thereof will be omitted herein.

It can be understood that the above embodiments and examples are merely exemplary embodiments employed to illustrate the principles of the disclosure, and the disclosure is not limited thereto. Various modifications and improvements can be made by those skilled in the art without departing from the spirit and scope of the disclosure. These modifications and improvements are also considered to be within the scope of the disclosure.

1. A back plate for OLED display substrate comprising a pixel definition layer, wherein the pixel definition layer comprises a body layer and an interface layer disposed on surface of the body layer, and the interface layer exhibits different lyophilic or lyophobic properties with respect to a functional layer of the OLED depending on the temperature of the interface layer;
wherein the pixel definition layer comprises a plurality of pixel openings arranged with an interval therebetween, and the interface layer cover sidewalls of the pixel opening.

2. The back plate according to claim 1, wherein the interface layer exhibits lyophobic to the functional layer of the OLED when the temperature of the interface layer exceeds a first predetermined temperature; whereas the interface layer exhibits lyophilic to the functional layer of the OLED when the temperature of the interface layer is equal to or lower than the first predetermined temperature.

3. The back plate according to claim 2, wherein the interface layer comprises a temperature responsive material including any one of polystyrene-polyvinyl methyl ether, poly(caprolactone-styrene-acrylonitrile) copolymer, poly(methyl methacrylate-styrene-acrylonitrile) copolymer, poly(N-isopropyl acrylamide) and the combinations thereof.

4. The back plate according to claim 3, wherein the interface layer further comprises a plurality of nanoparticles, the nanoparticle comprises a nanocore having magnetic responsiveness and a shell covering the nanocore, wherein the nanoparticles accounts for no more than 5% by mass in the pixel definition layer, and the nanoparticles has a particle size of 10 nm to 30 nm.

5. The back plate according to claim 4, wherein the nanocore having magnetic responsiveness comprises ferroferric oxide particles and/or face-centered ferric oxide particles, and the shell comprises silicon dioxide.

6. The back plate according to claim 3, wherein the temperature responsive material is attached to the body layer by coupling reaction, so as to form the interface layer.

7. The back plate according to claim 6, wherein the temperature responsive material is bonded to the surface of the body layer by reacting with vinyl groups located on the surface of the body layer, so as to form the interface layer.

8. The back plate according to claim 1, wherein the interface layer exhibits lyophobic to the functional layer of the OLED when the temperature of the interface layer is lower than a second predetermined temperature; the interface layer exhibits lyophilic to the functional layer of the OLED when the temperature of the interface layer is higher than the second predetermined temperature; and the interface layer comprises a temperature responsive material selected from any one of polystyrene-polyisoprene, poly(ethylene oxide)-poly(propylene oxide), polyisobutylene-polydimethylsiloxane and the combinations thereof.

9. An OLED display substrate comprising the back plate according to claim 1, and a plurality of functional layers including a plurality of common layers and a light emitting layer located between two common layers.

10. A display device comprising the OLED display substrate according to claim 9.

11. A method for manufacturing the back plate according to claim 1, comprising a step of forming a pixel definition layer which comprises the following steps:
mixing a plurality of the nanoparticles with a solution of the temperature responsive material to obtain an initial mixture, wherein the nanoparticle comprises a nanocore having magnetic responsiveness and a shell covering the nanocore, the nanoparticles accounts for no more than 5% by mass in the pixel definition layer, and the nanoparticles has a particle size of 10 nm to 30 nm; the temperature responsive materials include any one of polystyrene-polyvinyl methyl ether, poly(caprolactone-styrene-acrylonitrile) copolymer, poly(methyl methacrylate-styrene-acrylonitrile) copolymer, poly(N-isopropyl acrylamide) and the combinations thereof;
mixing the initial mixture with a stock solution of the body layer to obtain an intermediate mixture;
coating the intermediate mixture on a base substrate to form an initial layer;
patterning the initial layer to obtain an initial pixel definition layer having a shape consistent with that of the pixel definition layer; and
disposing the base substrate with the initial pixel definition layer thereon in a magnetic field and curing the initial pixel definition layer, such that the stock solution of the body layer is cured to obtain the body layer, and that meanwhile the nanoparticles grafted with the temperature responsive material on their surface move to the surface of the body layer and are cured to form the interface layer, wherein the nanocore having magnetic responsiveness comprises ferroferric oxide particles and/or face-centered ferric oxide particles, and the shell covering the nanocore comprises silicon dioxide.

12. The method for manufacturing the back plate according to claim 11, wherein the nanocore having magnetic responsiveness comprises ferroferric oxide particles and/or face-centered ferric oxide particles, and the shell comprises silicon dioxide.

13. A method for manufacturing the back plate according to claim 1, comprising a step of forming a pixel definition layer which comprises the following steps:
forming the body layer;
plasma-processing the body layer by using a plasma;
providing a coupling agent on the surface of the body layer after plasma-processing;
coating a solution of the temperature responsive material including any one of polystyrene-polyvinyl methyl ether, poly(caprolactone-styrene-acrylonitrile) copolymer, poly(methyl methacrylate-styrene-acrylonitrile) copolymer, poly(N-isopropyl acrylamide) and the combinations thereof; and
reacting the temperature responsive material with the coupling agent to form the interface layer.

14. The method for manufacturing the back plate according to claim 13, wherein the coupling agent is a silane coupling agent with vinyl group.

15. A method for manufacturing an OLED display substrate, comprising:
manufacturing the back plate 1 according to claim 1;
forming a plurality of functional layers, which comprises forming each common layers and forming a light emitting layer;
wherein forming each common layers comprises:
adjusting the process temperature such that the surface of the interface layer exhibits lyophilic;
coating material for a common layer on the surface of the interface layer; and
adjusting the process temperature such that the surface of the interface layer exhibits lyophobic, which allows the material for the common layer to be concentrated into pixel openings of the pixel definition layer, and further be cured to form a common layer;
forming the light emitting layer include:
adjusting the process temperature such that the surface of the interface layer exhibits lyophobic;
printing material for the light emitting layer in the pixel openings of the pixel definition layer to form the light emitting layer.
